(19) United States
(12) Patent Application Publication
(10) Pub. No.: US 2025/0231492 A1
(43) Pub. Date: Jul. 17, 2025

(54) MANUFACTURE OF INTEGRATED CIRUIT USING POSITIVE TONE PHOTOPATTERNABLE DIELECTRIC INCLUDING HIGH SILICON CONTENT POLYSILSESQUIOXANE

(71) Applicant: SUNTIFIC MATERIALS (WEIFANG), LTD., Weifang, Shandong (CN)

(72) Inventor: Sam SUN, Columbia, MO (US)

(21) Appl. No.: 18/682,426

(22) PCT Filed: Jun. 30, 2023
(86) PCT No.: PCT/CN2023/105369

§ 371 Date: Feb. 8, 2024

(51) Int. Cl. G03F 7/26; C08G 77/08; G03F 7/00; G03F 7/004; G03F 7/075; G03F 7/16; G03F 7/20; G03F 7/32; G03F 7/38; G03F 7/40

(52) U.S. Cl. CPC G03F 7/265; C08G 77/08; G03F 7/0035; G03F 7/0045; G03F 7/0757; G03F 7/162; G03F 7/165; G03F 7/2004; G03F 7/322; G03F 7/38; G03F 7/40

(57) ABSTRACT

Disclosed herein is a method including forming a first layer of a dielectric precursor composition on a substrate, the dielectric precursor composition including a silicon-containing polymeric resin, a catalyst capable of catalyzing condensation reaction of silicon-containing polymeric resin, and a photoacid generator, wherein the catalyst is deactivated by the presence of acid; exposing a portion the first layer of the dielectric precursor composition to radiation in a first image-wise manner to generate acid in the portion exposed to the radiation; heating the exposed first layer to form a cured dielectric resin in a portion of the first layer not exposed to the radiation; after heating, removing the dielectric precursor composition in the portion exposed to radiation; and filling the portion where the dielectric precursor has been removed with a metal. After cure, the cured resin of the dielectric precursor composition may include greater than 42 weight percent elemental silicon.

This application is a National Phase entry of International Application No. PCT/CN2023/105369 under § 371, filed Jun. 30, 2023, which is hereby incorporated by reference in its entirety.

### FIELD

This disclosure relates to a method of forming metal patterns in dielectric materials, particularly forming interconnects for integrated circuits.

### BACKGROUND

Integrated circuits can comprise a semiconductor substrate with one or more layers of dielectric material having conductive interconnects formed by metal vias or trenches formed in the dielectric material. A typical process for forming such a structure can involve forming a dielectric layer, applying a photoresist or photo-imageable hard mask, imaging and developing the photoresist to expose a portion (or region) of the dielectric layer, etching the dielectric layer to form a via and/or trench, and filling the via and/or trench with metal.

For example, as shown in FIG. 1(a)-(c), a photoresist 11 is applied over a non-photoactive dielectric material 12, which is on a substrate 13. The substrate 13 can comprise, for example a metal, a semiconductor, or a dielectric material or a combination of two or more thereof. For example, the substrate can have a metal top layer or can comprise metal features (e.g., lines) in a dielectric to which subsequent metal features can be connected using the method as shown. In FIG. 1(a), the photoresist 11 has been exposed to activating wavelengths of radiation in an image-wise pattern and developed to remove a portion of the photoresist 11 to expose a portion of the non-photoactive dielectric material 12. In FIG. 1(b), the non-photoactive dielectric material 12 has been etched (e.g., by reactive ion etching, RIE), to form a void 14 (e.g., a via or a trench) extending to the substrate 13. The etching also removed the photoresist. In FIG. 1(c), the void 14 has been filled with a metal 15 to form a portion of an interconnect.

As another example, in FIG. 2(a)-(f), a dual damascene method is shown. In FIG. 2(a), a photoresist 11 has been exposed to activating wavelengths of radiation and developed to remove a portion of the photoresist 11 to expose a portion of a non-photoactive dielectric material 12. In FIG. 2(b), the non-photoactive dielectric material 12 has been etched (e.g., by reactive ion etching, RIE), to remove the photoresist 11 and form a void 14 for a via. In FIG. 2(c), a second photoresist 11 has been applied over the non-photoactive dielectric material 12 and filling the void 14. In FIG. 2(d), the photoresist 11 has been exposed to activating wavelengths of radiation in an image-wise pattern and developed to remove a portion of the photoresist 11 to expose a portion of the non-photoactive dielectric material 12. In FIG. 2(e), the photoresist 11 and a portion of the non-photoactive dielectric material 12 have been removed by etching to form a void 14 having a first region 14v for a via and a second region 14t for a trench. In FIG. 2(f) the void has been filled with a metal 15.

Examples of photoresists include hydrocarbon based photoresists (e.g., polyhydroxystyrene and polymethacrylate based compositions that include photoactive compounds or moieties) and silicon hard masks (see e.g., US 2010/0261097, the content of which is incorporated herein by reference in its entirety). This process can be time-consuming and costly.

Various methods using photo-patternable dielectrics have been proposed to eliminate the need for photoresists and etching. See e.g., U.S. Pat. No. 8,029,971, WO 2005/109490, and WO 2011/057832, the contents of which are incorporated herein by reference in their entirety. However, the methods of U.S. Pat. No. 8,029,971 and WO 2011/057832, using silicon-based dielectrics, remain cumbersome as they require a bake step after exposing and before developing the dielectric material, and a cure step after developing the dielectric layer. WO 2005/109490 involves a decomposable, photosensitive trench layer material that is at least partially removed by heating, decomposing and diffusion through a top layer to form air gaps in the trench layer.

A need remains for a more efficient method of forming integrated circuits.

### SUMMARY

Disclosed herein is a method of forming a metal interconnect in a dielectric material comprising: forming a first layer of a dielectric precursor composition on a substrate, the dielectric precursor composition comprising a silicon-containing polymeric resin, a catalyst capable of catalyzing condensation reaction of silicon-containing polymeric resin, and a photoacid generator, wherein the catalyst can be deactivated by the presence of acid such that it loses the capability of catalyzing the condensation reaction; exposing a first portion of the first layer of the dielectric precursor composition to radiation in a first image-wise manner to generate acid in the first portion exposed to the radiation and form an exposed first layer; heating the exposed first layer to form a cured dielectric resin in a second portion of the first layer not exposed to the radiation; after the heating, removing the dielectric precursor composition in the first portion exposed to radiation; and filling the first portion where the dielectric precursor has been removed with a metal.

Also disclosed is an article made by such method. The cured dielectric resin in the article can have a dielectric constant of less than 4, preferably less than 3. The layer of cured dielectric resin at a thickness up to 1.5 micrometers is resistant to cracking at temperatures up to 400° C.

Also disclosed herein is a composition comprising: a curable silicon-containing polymeric resin, a catalyst capable of catalyzing condensation reaction of silicon-containing polymeric resin, a photoacid generator, and an organic solvent, wherein, when cured, the silicon-containing polymeric resin comprises greater than 42, preferably at least 42.5, and more preferably at least 43 weight percent elemental silicon, based on total weight of the cured resin.

### BRIEF DESCRIPTION OF THE DRAWINGS

Referring now to the figures, which are exemplary embodiments, and wherein the like elements are numbered alike.

FIGS. 1(a)-(c) show an example of a prior art method of forming metal features in a dielectric using a photoresist.

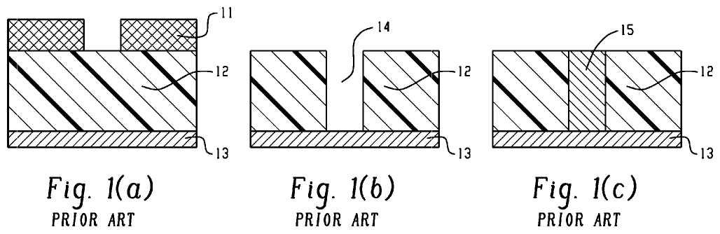

FIGS. 2(a)-(f) show an example of a dual damascene prior art method forming metal features in a dielectric using a photoresist.

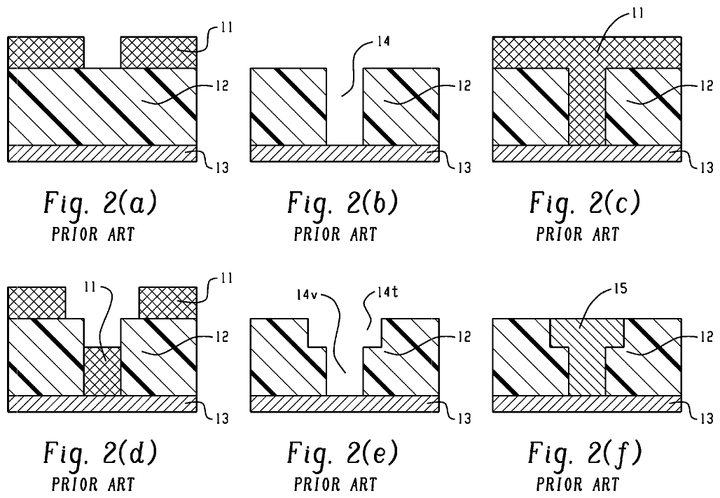

FIGS. 3(a)-(c) show an example of a method of forming a metal interconnect using a positive tone photopatternable dielectric as disclosed herein.

FIGS. 4(a)-(e) show an example of a dual damascene method for forming a metal interconnect using a positive tone photopatternable dielectric as disclosed herein.

FIGS. 5(a)-(f) show an example of a method of forming a metal interconnect using a positive tone photopatternable dielectric as disclosed herein.

### DETAILED DESCRIPTION

The method as described herein includes forming a layer of a photopatternable dielectric precursor composition on a substrate, exposing the layer to activating wavelengths of radiation, heating to cure portions of the layer not exposed to the radiation, removing the exposed portions of the layer to form a void region, and filling the void region with metal.

The process can avoid need for RIE, avoid need for photoresists remove process steps and related equipment and materials.

The substrate can comprise a metal, a semiconductor, a dielectric material, or a combination of two or more thereof. The substrate can comprise a metal film or metal features in a dielectric material on a top layer thereof such that an additional metal incorporated in the method disclosed herein contacts such metal. For example, the substrate can include a semiconducting material such as Si, SiGe, SiGeC, SiC, GaAs, InAs, InP, or other Group III/V or Group II/VI compound semiconductors. The substrate can include, for example, a silicon wafer or process wafer, such as that produced in various steps of a semiconductor manufacturing process, such as an integrated semiconductor wafer. The substrate can include multiple layers or can be a single layer. The substrate can include a layered substrate, such as, for example, Si/SiGe, Si/SiC, silicon-on-insulator (SOI), or silicon germanium-on-insulator (SGOI). A substrate comprising a combination comprising at least one of the foregoing can be used.

The silicon dielectric precursor composition can comprise a silicon-containing resin, a catalyst capable of catalyzing a condensation reaction of the silicon-containing resin, and a photoacid generator, wherein the catalyst can be deactivated by the presence of acid such that it loses the capability of catalyzing the condensation reaction. Thus, when a region of a coating of the silicon dielectric precursor composition is exposed to activating radiation, an acid is formed and the catalyst is deactivated. Subsequent cure takes place in unexposed region(s). Development in a suitable developing solution removes the exposed region(s). Thus, the silicon dielectric precursor composition is a positive tone composition.

The silicon-containing polymeric resin can be prepared from one or more monomers with molecular structures of

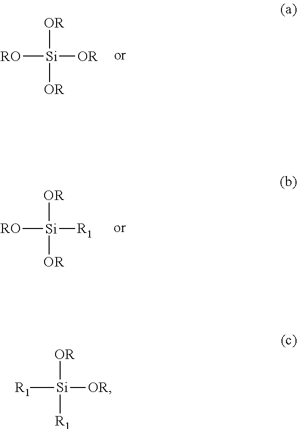

or a combination of two or more thereof, preferably (a), (b), or (a) and (b). Each R is independently in each occurrence hydrogen or an alkyl group of 1 to 4 carbon atoms, preferably 1 to 3 carbon atoms, and more preferably 1 or 2 carbon atoms, R is preferably an alkyl group of 1 or 2 carbon atoms, and each R₁ is independently at each occurrence a monovalent organic group having 1 to 30 carbon atoms, and optionally including 1 to 5 heteroatoms selected from N, O, P, S, or a combination of two or more thereof. For example, R₁ can be an alkyl group having 1 to 30 carbon atoms, an aryl group having 6 to 30 carbon atoms, an alkene group having 2 to 30 carbon atoms, or an alicyclic group having 3 to 30 carbon atoms, each of which optionally includes
—O—, —CO—, —OCO—, —COO—, or —OCOO— as part of its structure. R₁ can be further substituted by one or more epoxy groups. R₁ is preferably an alkyl group of 1 or 2 carbon atoms to provide a cured resin with silicon content above 42 weight percent, based on a total weight of the cured resin.

Examples of preferred monomers include of methyltrimethoxy silane, tetraethoxysilane, tetramethoxysilane, tetraethoxysilane, methyltrimethoxysilane, methyltriethoxysilane, ethyltrimethoxysilane, ethyltriethoxysilane, vinyltrimethoxysilane, vinyltriethoxysilane, propyltrimethoxysilane, propyltriethoxysilane, isopropyltrimethoxysilane, isopropyltriethoxysilane, butyltrimethoxysilane, butyltriethoxysilane, isobutyltrimethoxysilane, isobutyltriethoxysilane, allyltrimethoxysilane, allyltriethoxysilane, cyclopentyltrimethoxysilane, cyclopentyltriethoxysilane, cyclohexyltrimethoxysilane, cyclohexyltriethoxysilane, cyclohexenyltrimethoxysilane, cyclohexenyltriethoxysilane, phenyltrimethoxysilane, phenyltriethoxysilane, benzyltrimethoxysilane, benzyltriethoxysilane, phenethyltrimethoxysilane, phenethyltriethoxysilane, dimethyldimethoxysilane, dimethyldiethoxysilane, diethyldimethoxysilane, diethyldiethoxysilane, methylethyldimethoxysilane, methylethyldiethoxysilane, dipropyldimethoxysilane, dibutyldimethoxysilane, methylphenyldimethoxysilane, methylphenyldiethoxysilane, trimethylmethoxysilane, dimethylethylmethoxysilane, dimethylphenylmethoxysilane, dimethylbenzylmethoxysilane, dimethylphenethylmethoxysilane, or the like, or a combination of two or more thereof.

The polymerization of the monomers can occur in an organic solvent. Exemplary organic solvents for use in the polymerization include methanol, ethanol, 1-propanol, 2-propanol, 1-butanol, 2-butanol, 2-methyl-1-propanol, acetone, acetonitrile, tetrahydrofuran, toluene, hexane, ethyl acetate, methyl ethyl ketone, methyl isobutyl ketone, cyclohexanone, methyl amyl ketone, butanediol monomethyl ether, propylene glycol monomethyl ether, ethylene glycol monomethyl ether, butanediol monoethyl ether, propylene glycol monoethyl ether, ethylene glycol monoethyl ether, propylene glycol dimethyl ether, diethylene glycol dimethyl ether, propylene glycol monomethyl ether acetate, propylene glycol monoethyl ether acetate, ethyl pyruvate, butyl acetate, methyl 3-methoxypropionate, ethyl 3-ethoxypropionate, tert-butyl acetate, t-butyl propionate, propylene glycol mono-t-butyl ether acetate, y-butyrolactone, or the like, or a combination of two or more thereof. The organic solvent can be propylene glycol methyl ether or propylene glycol methyl ether acetate.

The polymerization of the monomers can occur in the presence of one or more polymerization catalysts. The polymerization catalyst can be an acid catalyst. Exemplary acid catalysts include organic acids, such as formic acid, acetic acid, oxalic acid, maleic acid, methanesulfonic acid, benzenesulfonic acid, toluenesulfonic acid, or the like, or a combination of two or more thereof, or inorganic acids such as hydrofluoric acid, hydrochloric acid, hydrobromic acid, sulfuric acid, nitric acid, perchloric acid, phosphoric acid, or the like, or a combination of two or more thereof. The acid catalyst can be acetic acid. The acid catalyst can be used in any suitable amount, such as 1 to 10 weight percent of total content in the reactors.

The polymerization can occur at temperatures of from 0° C. to 110° C., 20° C. to 110° C., 50° C. to 110° C., or 80° C. to 110° C.

Volatile alkanols formed during the condensation reaction can be removed by distillation as the reaction proceeds. The distillate can also include the acid catalyst, water, and/or the solvent. A nitrogen stream flushed through the reactor can assist with the distillation. The removal of volatile alkanols can occur during or after the polymerization reaction.

The silicon-containing polymeric resin so formed can comprise a polysiloxane, polysilsesquioxane, or a combination thereof. For example, the silicon-containing polymeric resin comprise both polysiloxane and polysilsesquioxane. The silicon containing polymeric resin can comprise a cross-linked network structure. The network can include a complex and diverse set of molecular structures of polysiloxanes and polysilsesquioxanes. For example, the network structures can include a variety of structures including the following molecular structure:

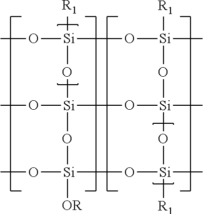

wherein R and R1 are as defined herein. However, the above simplified structure is not necessarily the exact and complete description of the silicon-containing polymeric resin, such that the monomers and polymerization process provide the most accurate description of the polymer.

The weight average molecular weight (M_{w}) of the silicon-containing polymeric resin, before cure, can be from 1,000 to 50,000 grams per mole (g/mol), from 1,500 to 30,000 g/mol, from 2,000 to 20,000 g/mol, or from 3,000 to 10,000 g/mol. M_{w} can be determined using Gel Permeation Chromatography (GPC) with polystyrene standards as described in Williams and Ward, J. Polymer. Sci., Polymer. Letters, 6, 621 (1968), the content of which is incorporated herein by reference in its entirety.

Exemplary silicon-containing polymeric resins can include substituted siloxane, substituted silsesquioxane, substituted polysiloxane, or substituted polysilsesquioxane, such as substituted methylsiloxane, substituted methylsilsesquioxane, substituted phenylsiloxane, substituted phenylsilsesquioxane, substituted methylphenylsiloxane, substituted methylphenylsilsesquioxane, substituted dimethylsiloxane, substituted diphenylsiloxane, substituted methylphenylsiloxane, substituted polyphenylsilsesquioxane, substituted polyphenylsiloxane, substituted polymethylphenylsiloxane, substituted polymethylphenylsilsesquioxane, substituted polymethylsiloxane, substituted polymethylsilsesquioxane, or a combination thereof.

The silicon-containing polymeric resin can be included in the dielectric precursor composition in an amount of, for example, 2 to 50, 4 to 40, or 10 to 30 weight percent, based on a total weight of the dielectric precursor composition. A composition having the silicon-containing polymeric resin in this weight range can produce film thickness of 100 nanometers to 4 micrometers at typical spin coating speeds, e.g., 500 to 2000 revolutions per minute (RPM).

The catalyst in the silicon dielectric precursor composition is capable of catalyzing a condensation reaction of the silicon-containing resin. That is, the silicon-containing resin can undergo further crosslinking via condensation. The catalyst is deactivated by an acid, such as the photoacid generated by the photoacid generator. An acid-deactivated catalyst, as used herein, refers to a catalyst that is deactivated in the presence of an acid. This catalyst can be referred to as the cure catalyst.

The cure catalyst can include a quaternary ammonium and/or an amine, such as, for example, methylamine, ethylamine, propylamine, butylamine, ethylenediamine, hexamethylenediamine, dimethylamine, diethylamine, ethylmethylamine, trimethylamine, triethylamine, tripropylamine, tributylamine, cyclohexylamine, dicyclohexylamine, monoethanolamine, diethanolamine, dimethyl monoethanolamine, monomethyl diethanolamine, triethanolamine, hexamethylenetetramine, aniline, N,N-dimethylaniline, N,N-dimethylaminopyridine, pyrrole, piperazine, pyrrolidine, piperidine, benzyltriethylammonium chloride (BTEAC), tetramethylammonium chloride (TMAC), guanidine carbonate, tetramethylammonium hydroxide (TMAH), tetramethylammonium acetate (TMAA), tetrabutylammonium hydroxide (TBAH), tetrabutylammonium acetate (TBAA), cetyltrimethylammonium acetate (CTAA), tetramethylammonium nitrate (TMAN), or a combination of two or more thereof. Other exemplary catalysts include (2-hydroxyethyl)trimethylammonium chloride, (2-hydroxyethyl)trimethylammonium hydroxide, (2-hydroxyethyl)trimethylammonium acetate, (2-hydroxyethyl)trimethylammonium formate, (2-hydroxyethyl)trimethylammonium nitrate, (2-hydroxyethyl)trimethylammonium benzoate, tetramethylammonium formate, or a combination of two or more thereof.

The amount of the cure catalyst can be about 0.0005 to about 0.2, or about 0.001 to about 0.05, weight percent (wt %), based on a total weight of the dielectric precursor composition. The amount of the catalyst can be about 0.045 to about 4, or 0.01 to about 0.5 wt %, based on the weight of the silicon-containing polymeric resin.

The photoacid generator is a compound which generates an organic acid by irradiation with actinic ray or radiation, and a known compound can be used. A sensitive wavelength of the photoacid generator can be, for example, a wavelength of 10 to 450, or 300 to 450 nanometers (nm). In other words, the photoacid generator can be a compound which generates an acid in response to actinic ray in the above-described wavelength range. In addition, a pKa of the acid generated from the photoacid generator can be 4.0 or less or 3.0 or less.

The photoacid generator can comprise an onium salt, a triazine compound (such as a halomethylated triazine compound and more specifically, for example, a trichloromethyl-s-triazine compound), an oxime sulfonate compound, a bissulfonyldiazomethane compound, an imide sulfonate compound, a diazodisulfone compound, a disulfone compound, or a nitrobenzylsulfonate compound (such as an o-nitrobenzylsulfonate compound). The photoacid generator can include a sulfonium or iodinium salt, such as a compound comprising a sulfonium cation or sulfonate, or a methide or iodinium cation or sulfonate. Exemplary sulfonium cations include triphenylsulfonium and tris(4-tert-butoxyphenyl)sulfonium. Exemplary sulfonates include trifluoromethanesulfonate and perfluoro-1-butanesulfonate. An exemplary methide includes tris(trifluoromethyl)methide. Exemplary iodonium cations are aryliodonium cations including diphenyliodonium and bis(4-tert-butylphenyl)iodonium. Exemplary sulfonates include trifluoromethanesulfonate and perfluoro-1-butanesulfonate.

Exemplary photoacid generators include onium salts such as triphenylsulfonium trifluoromethanesulfonate, triphenylsulfonium trifluoroacetate, 4-methoxyphenyldiphenylsulfonium trifluoromethanesulfonate, 4-methoxyphenyldiphenylsulfonium trifluoroacetate, 4-phenylthiophenyldiphenylsulfonium trifluoromethanesulfonate, 4-phenylthiophenyldiphenylsulfonium, trifluoroacetate·diphenyliodonium trifluoromethane-sulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsulfonium trifluoromethane-sulfonate, bis(p-tert-butoxyphenyl)phenylsulfonium trifluoromethane-sulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutane sulfonate, triphenylsulfonium butanesulfonate, trimethylsulfonium trifluoromethanesulfonate, trimethylsulfonium p-toluenesulfonate, cyclohexylmethyl(2-oxocyclohexyl)sulfonium trifluoromethane-sulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, trinaphthylsulfonium trifluoromethanesulfonate, cyclohexylmethyl(2-oxocyclohexyl)sulfonium trifluoromethane-sulfonate, (2-norbornyl)methyl(2-oxocyclohexyl)sulfonium trifluoro-methanesulfonate, ethylenebis[methyl(2-oxocyclopentyl)sulfonium trifluoro-methanesulfonate], 1,2′-naphthylcarbonylmethyltetrahydrothiophenium triflate, diphenyliodonium trifluoroacetate, diphenyliodonium trifluoromethanesulfonate, 4-methoxyphenylphenyliodonium trifluoromethanesulfonate, 4-methoxyphenylphenyliodonium trifluoroacetate, phenyl-4-(2′-hydroxy-1′-tetradecaoxy)phenyliodonium trifluoromethanesulfonate, 4-(2′-hydroxy-1′-tetradecaoxy)phenyliodonium hexafluoroantimonate, phenyl-4-(2′-hydroxy-1′-tetradecaoxy)phenyliodonium p-toluenesulfonate, or the like, or a combination of two or more thereof.

Exemplary diazomethane compounds include bis(benzenesulfonyl)diazomethane, bis(p-toluenesulfonyl)diazomethane, bis(xylenesulfonyl)diazomethane, bis(cyclohexylsulfonyl)diazomethane, bis(cyclopentylsulfonyl)diazomethane, bis(n-butylsulfonyl)diazomethane, bis(isobutylsulfonyl)diazomethane, bis(isoamylsulfonyl)diazomethane, 1-tert-amylsulfonyl-1-(tert-butylsulfonyl)diazomethane, or the like, or a combination of two or more thereof.

Exemplary triazine compounds include 2-(3-chlorophenyl)-bis(4,6-trichloromethyl)-s-triazine, 2-(4-methoxyphenyl)-bis(4,6-trichloromethyl)-s-triazine, 2-(4-methylthiophenyl)-bis (4,6-trichloromethyl)-s-triazine, 2-(4-methoxy-β-styryl)-bis(4,6-trichloromethyl)-s-triazine, 2-piperonyl-bis (4,6-trichloromethyl)-s-triazine, 2-[2-(furan-2-yl)ethenyl]-bis (4,6-trichloromethyl)-s-triazine, 2-[2-(5-methyl)furan-2-yl)ethenyl]-his (4,6-trichloromethyl)-s-triazine, 2-[2-(4-diethylamino-2-methylphenyl)ethenyl]-bis(4,6-trichloromethyl)-s-triazine, 2-(4-methoxynaphthyl)-bis(4,6-trichloromethyl)-s-triazine, or the like, or a combination of two or more thereof.

Exemplary imide sulfonate compounds include trifluoromethylsulfonyloxybicyclo[2.2.1]-hept-5-en-dicarboxyimide, succinimide trifluoromethylsulfonate, phthalimidetrifluoromethylsulfonate, N-hydroxynaphthalimidemethanesulfonate, N-hydroxy-5-norbornene-2,3-dicarboxyimide propanesulfonate, or the like, or a combination of two or more thereof.

A specific example of the photoacid generator is 2-(4-methoxyphenyl)([((4-methylphenyl)sulphonyl)oxy]imino)acetonitrile.

The content of the photoacid generator can be about 0.05 to 3, or 0.1 to 2, or 0.1 to 1, or 0.2 wt %, based on the total solid content of the composition.

The mole ratio of photoacid generator to catalyst in the composition can be, for example, 0.5:1 to 10:1, or 0.5:1 to 5:1, or 0.5:1 to 1.5:1.

The cured silicon-containing dielectric can have a high silicon atom content,—e.g., greater than 35, greater than 38, greater than 39, greater than 40, greater than 41, greater than 42, at least 42.5, or at least 43 weight percent, up to 46, or up to 45 weight percent atomic silicon, based on total weight of the cured silicon-containing dielectric.

Forming the layer of the photopatternable dielectric precursor composition on the substrate can include applying a coating composition to the substrate. The composition can comprise the silicon-containing polymeric resin, the catalyst (i.e., the acid deactivated cure catalyst), the photoacid generator, and a coating solvent.

Exemplary coating solvents include solvents that are not part of the hydrocarbon family of solvent compounds, such as ketones, including acetone, diethyl ketone, methyl ethyl ketone, or the like, alcohols, esters, ethers, or amines. Examples of solvents include propylene glycol methyl ether (PGME), propylene glycol methyl ether acetate (PGMEA), propylene glycol propyl ether (PGPE), and ethyl lactate (EL).

The solvent can be included in the dielectric precursor composition in an amount of 50 wt % to 98 wt %, 55 wt % to 95 wt %, or 65 wt % to 90 wt %, based on the total weight of the composition.

Suitable methods of applying can include spin coating, spray coating, and the like. The solvent is removed to form a solid layer of the photopatternable dielectric precursor composition.

Additional optional components of the coating composition can include a film modifier to control diffusion of ingredients in the film, a surfactant, or the like, or a combination of two or more thereof.

The film modifier can be polymer, oligomer, or a non-polymeric compound. The M_{w} of the polymer or oligomer used as the film modifier can be less than 5,000 g/mol, or can be less than 2,000 g/mol, such as 200 to 5,000 g/mol, or 500 to 2,000 g/mol. Molecules of film modifiers have to be small enough to fill in the film pores. A film modifier can be a hydrocarbon compound, and preferably can be a silicon-containing compound. In an aspect, at least one hydroxyl group is attached to each molecule of the film modifier. The hydroxyl group can participate in the condensation reaction of the film resin. Exemplary hydrocarbon film modifiers include polyols, such as polyetherdiol, glycerol, 2-(hydroxymethyl)-1,3-propanediol, 1,3-dihydroxypropan-2-yl dihydrogen phosphate, ethylene glycol, 1,3-propylene glycol, 1,4-butanediol, 1,5-pentanediol, 1,6-hexanediol, 1,7-heptanediol, 1,8-octanediol, 1,9-nonanediol, 1,10-decanediol, and/or the like. Examples of the branched alkylenediol can include neopentylglycol, 2,4-diethyl-1,5-pentanediol, 2,4-dibutyl-1,5-pentanediol, 3-methyl-1,5-pentanediol, 1-methylethylene glycol, 1-ethylethylene glycol, diethylene glycol, triethylene glycol, tetraethylene glycol, dipropylene glycol, tripropylene glycol, 1,1,1-tris(hydroxymethyl)ethane, 2-hydroxymethyl-1,3-propanediol, 2-ethyl-2-(hydroxymethyl)-1,3-propanediol, 2-hydroxymethyl-2-propyl-1,3-propanediol, 2-hydroxymethyl-1,4-butanediol, 2-hydroxyethyl-2-methyl-1,4-butanediol, 2-hydroxymethyl-2-propyl-1,4-butanediol, 2-ethyl-2-hydroxyethyl-1,4-butanediol, 1,2,3-butanetriol, 1,2,4-butanetriol, 3-(hydroxymethyl)-3-methyl-1,4-pentanediol, 1,2,5-pentanetriol, 1,3,5-pentanetriol, 1,2,3-trihydroxyhexane, 1,2,6-trihydroxyhexane, 2,5-dimethyl-1,2,6-hexanetriol, tris(hydroxymethyl)nitromethane, 2-methyl-2-nitro-1,3-propanediol, 2-bromo-2-nitro-1,3-propanediol, 1,2,4-cyclopentanetriol, 1,2,3-cyclopentanetriol, 1,3,5-cyclohexanetriol, 1,3,5-cyclohexanetrimethanol, butane-1,2,3,4-tetrol(butane-1,2,3,4-tetrol), 2,2-bis(hydroxymethyl)-1,3-propanediol, pentane-1,2,4,5-tetrol, or the like, or a combination of two or more thereof. The film modifier can be 1,1,1-tris(hydroxymethyl)ethane, pentaerythritol, or a combination of two ore more thereof. Exemplary silicon-containing film modifiers include silanols such as diphenylsilanediol, diisobutylsilanediol, 1,4-bis(hydroxyldimethylsilyl)benzene, 4-vinylphenylsilanediol, or the like, or a combination of two or more thereof. The film modifier can be no greater 30 wt %, or no greater than 10 wt %, of the total weight of the resin. Concentrations of film modifier in compositions are used to control diffusion length of the catalyst, photoacid generator, and quencher. Mentioned is an aspect in which multiple film modifiers are be used in the composition.

Removal of the solvent can be done as part of the coating (e.g., spin coating) process. If the solvent is not sufficiently removed in that process, additional steps such as baking (e.g., on a hotplate surface) at 40 to 120° C., 50 to less than 100° C., or 60 to less than 80° C., for 15 to 120 seconds or 30 to 60 seconds, can occur. This baking step must not be long enough or hot enough to cause cure of the silicon-containing polymeric resin so that the dried film remains soluble in the developer solution.

Exposing can comprise exposure to an activating wavelength of radiation. To generate a pattern in the photopatternable dielectric precursor, the exposure is an image-wise exposure. This can occur through a mask or by direct address with a laser. The activating wavelength can be, for example, in the range of 10 to 400 nm, or a specific wavelength such as 365 nanometers, 248 nanometers, 193 nanometers, or 13.5 nanometers. A combination comprising at least one of the foregoing wavelengths can be used.

The exposure deactivates the catalyst. During a subsequent heating to cause cure, the silicon-containing resin precursor cures (e.g., cross-links) only in the regions not exposed to the radiation. The cure can occur at temperatures of 60 to 120° C., or 80 to 110° C., for 30 to 120 seconds.

The exposed and cured silicon-containing dielectric can be developed with a solution comprising an organic solvents, particularly a polar organic solvent, or an alkaline aqueous solution. Examples of organic solvents include, but are not limited to, cyclohexanone, methyl acetate, butyl acetate, ethyl acetate, isopropyl acetate, amyl acetate, isoamyl acetate, ethyl methoxyacetate, ethyl ethoxyacetate, propylene glycol monomethyl ether (PGME), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, or the like, or a combination of two or more thereof. Examples of the alkaline developer can include an aqueous solutions of an organic or an inorganic base, including tetramethylammonium hydroxide (TMAH), tetraethylammonium hydroxide, ethanolamine, propylamine, ethylenediamine, choline, potassium hydroxide, or sodium hydroxide. A specific example of a developer is an aqueous solution of tetramethylammonium hydroxide in a concentration ranging from 2.5 to 25 grams per liter. The development is performed under appropriately determined conditions; e.g., a temperature of 5 to 50° C. and a time of 10 to 600 seconds.

The thickness of the dielectric layer can be selected as appropriate for the interconnect structure being manufactured. For example, the thickness of the dielectric layer can be from 2, from 5, or from 10 nm up to 10,000, up to 5,000, up to 1,000, up to 900, up to 800, up to 700, up to 600, up to 500, up to 400, up to 300, up to 200, or up to 100 nm. A size of vias can be about 140 nm to 10 micrometers, or 40 to 1 micrometers in cross section or diameter Trenches or lines can be from 10 nm, or from 100 nm up to 10 micrometers, or up to 5 micrometers in width.

Filling with metal can comprise sputtering, physical vapor deposition, chemical vapor deposition, plasma enhanced vaporer deposition, atomic layer deposition, electroless plating, or a combination of two or more thereof. The metal can comprise tungsten, nickel, cobalt, copper, aluminum, gold, or silver.

After filling, the layer can be planarized, e.g., using chemical mechanical polishing to planarize a surface of the layer.

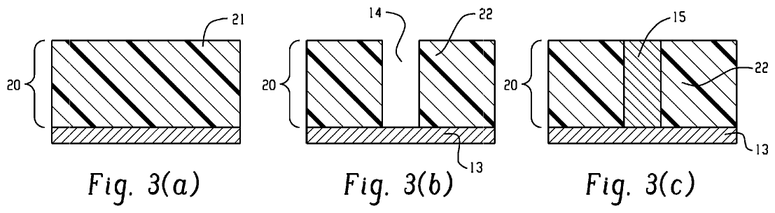

Referring to FIGS. 3(a)-(c), as one example of the method as disclosed herein, a layer 20 of photopatternable dielectric precursor composition 21 is formed on substrate 13. In FIG. 3(b), the photopatternable dielectric precursor has been image-wise exposed to activating radiation, and the layer 20 has been heated to form a cured dielectric 22, and the portion of the layer that was exposed to the activating radiation (“first portion”) is removed (e.g., using a developing solution) to form a void 14 between regions (“second portion”) of the cured dielectric 22. In FIG. 3(c) a metal 15 has been filled into the void 14.

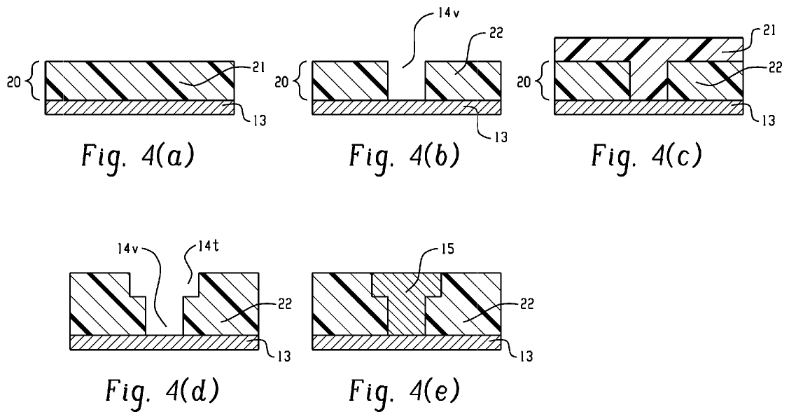

Referring to FIGS. 4(a)-(e), as one example of the method as disclosed herein, a layer 20 of photopatternable dielectric precursor composition 21 is formed on substrate 13. In FIG. 4(b), photopatternable dielectric precursor has been image-wise exposed to activating radiation, and the layer 20 has been heated to form a cured dielectric 22, and the portion of the layer that was exposed to the activating radiation (“first portion”) is removed (e.g., using a developing solution) to form a void 14v (e.g., a via) between regions (“second portion”) of the cured dielectric 22. In FIG. 4(c), additional photopatternable dielectric precursor composition 21 is applied, filling the void and covering the cured dielectric 22. In FIG. 4(d), the additional photopatternable dielectric precursor 21 has been image-wise exposed to activating radiation, and heated to form the cured dielectric 22, and the region of the layer that was exposed to the activating radiation (“first region”) is removed (e.g., using a developing solution) to form a void 14t (e.g., a trench). The voids 14v and 14t are in fluid communication with each other forming a contiguous void region. In FIG. 4(e) a metal 15 has been filled into the void 14t and 14v.

As an alternative to this approach, rather than removing the first portion of the first layer that was exposed to the activating radiation as shown in FIG. 4(b), to form void 14v, a second layer of a photopatternable dielectric precursor composition 21 can be formed over the exposed and cured (but not developed) photopatternable dielectric precursor composition. The second layer can then be exposed and cured, and the exposed, uncured of both the first and second layer developed simultaneously to arrive at a structure as shown in FIG. 4(d).

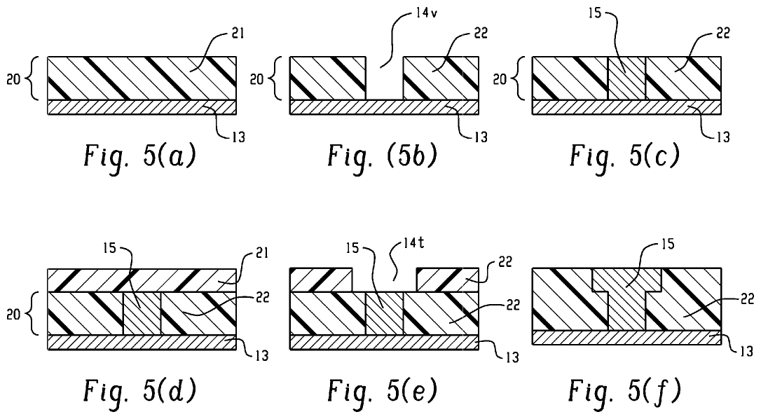

Referring to FIGS. 5(a)-(f), as one example of the method as disclosed herein, a layer 20 of photopatternable dielectric precursor composition 21 is formed on substrate 13. In FIG. 5(b), the photopatternable dielectric precursor has been image-wise exposed to activating radiation, and the layer 20 has been heated to form a cured dielectric 22, and the portion of the layer that was exposed to the activating radiation (“first portion”) is removed (e.g., using a developing solution) to form a void 14v (e.g., a via) between regions (“second portion”) of the cured dielectric 22. In FIG. 5(c), a metal 15 has been filled into the void 14v. Optionally, the top surface can be planarized after metallization and before proceeding to the next step. In FIG. 5(d), additional photopatternable dielectric precursor composition 21 is applied over the metal 15 and covering the cured dielectric 22. In FIG. 5(e), the additional photopatternable dielectric precursor has been image-wise exposed to activating radiation, and heated to form a cured dielectric 22, and the portion of the layer that was exposed to the activating radiation (“first region”) is removed (e.g., using a developing solution) to form a trench 14t (e.g., a trench). As shown in FIG. 5(e), at least a portion of the trench 14t overlies at least a portion of the metal 15. However, in other embodiments, no such overlap is present. In FIG. 5(f) a metal 15 has been filled into the trench 14t.

The process steps of applying, exposing, curing, developing and filling can be repeated for subsequent layers forming multi-layers of interconnects.

Planarization can occur to ensure a level surface for initiating a next layer. Particularly planarization using chemical mechanical polishing can occur after the metallization step.

After cure, the dielectric is resistant to chemicals. In addition, once cured, there is no or substantially no outgassing from the dielectric material.

The cured dielectric film can have a dielectric constant less than 4, or less than 3.5, and greater than 2, or greater than 2.5. The dielectric constant can be measured according to ASTMD150 on an impedance analyzer such as Model E4990A from Keysight.

An article comprising the metal features and cured dielectric made by the method as disclosed herein can be resistant to cracking. For example, such articles can show no cracking after heating to 400° C. Specifically, the cured dielectric at a thickness of 1.5 micrometers that has been baked at 400° C. for 30 minutes is cooled and no cracks were observed visually and by microscope.

The article can be an electronic device, such as a chip or integrated circuit or a system comprising such a device. Examples of such systems include computers, cell phones, transportation vehicles, appliances, manufacturing systems, robotic devices, and the like.

### EXAMPLES

### Example 1: Synthesis of Silicon-Containing Polymeric Resin and Formulation of Photo Patternable Dielectric

In a 500-mL round bottom flask, 60 grams of methyltrimethoxy silane, 30 grams of tetraethoxy silane, 250 grams of 1-methoxy-2-propanol acetate, 42 grams of water and 9 grams of acetic acid were combined, mixed well and distilled for 5 hours. The temperature of the flask contents was raised to the boiling point. Silicon-containing polymeric resin was recovered from in the flask.

### Example 2: Formulating Photo Patternable Dielectric and Process Conditions of Forming Dielectric Patterns

Six grams of silicon-containing polymeric resin obtained as in Example 1, 0.5 grams of 1-methoxy-2-porpanol acetate, 1 grams of 1-propoxy-2-propanol, 0.001 grams of benzenyl trimethyl ammonium chloride, and 0.01 grams of 2-(4-methoxyphenyl)([((4-methylphenyl)sulphonyl)oxy]imino)acetonitrile were combined in a container and mixed until all ingredients dissolved. This solution was spin-coated on a silicon wafer at a spin speed of 1000 revolution-per-minute on a silicon wafer. A film having a thickness of about 200 nm was formed on the surface of the wafer. No bake was needed after spin coating. This film is the photopatternable dielectric with a thickness of 200 nanometer. The wafer with these coatings was image-wise exposed to radiation having a wavelength of 365 nm to generate acid in the exposed regions. The wafer was then baked on a hot surface with a temperature of 120° C. for 60 seconds. Following this bake, the wafer was submerged in a 2.38 weight percent (wt %) aqueous solution of tetramethyl ammonium hydroxide in water for 10 to 40 seconds, forming the desired patterns form on the dielectric film. The pattern was then cured at 200° C. on a hotplate for 120 seconds.

### Example 3

The dielectric resin obtained as in Example 1 was tested by forming a spin-coated layer of 1.5 micrometers on the substrate, which was then baked at 400° C. for 30 minutes and then cooled. Visual inspection with and without microscope revealed no cracks.

### Example 4

The Silicon-containing polymeric resin obtained as in Example 1 was formed into a film and cured and tested for dielectric constant on a Model E4990A impedance analyzer from Keysight. The measured dielectric constant was 3.0.

### Example 5

A cured silicon resin from the resin obtained as in Example 1 was tested by inductively coupled plasma mass spectrometry (ICPMS) to determine silicon content. It was found to have a silicon content of about 43 weight percent, based on a total weight of the resin.

This disclosure further encompasses the following aspects.

Aspect 1: A method of forming metal interconnects in a dielectric material comprising forming a first layer of a dielectric precursor composition on a substrate the dielectric precursor composition comprising a silicon-containing polymeric resin, a catalyst capable of catalyzing condensation reaction of silicon-containing polymeric resin, and a photoacid generator, wherein the catalyst can be deactivated by the presence of acid such that it loses the capability of catalyzing the condensation reaction; exposing a portion the first layer of the dielectric precursor composition to radiation in a first image-wise manner to generate acid in the portion exposed to the radiation; heating the exposed first layer to form a cured dielectric resin in a portion of the first layer not exposed to the radiation; after heating, removing the dielectric precursor composition in the portion exposed to radiation; and filling the portion where the dielectric precursor has been removed with a metal.

Aspect 2: The method of Aspect 1 further comprising, after filling the first portion of the first layer where the dielectric precursor has been removed with the metal, applying a second layer of the dielectric precursor composition, exposing a first region of the second layer of the dielectric precursor composition to radiation in a second image-wise manner to generate acid in the first region exposed to the radiation, heating the exposed second layer to form cured dielectric resin in a second region of the second layer not exposed to the radiation; removing the dielectric precursor composition in the first region of the second layer exposed to radiation; and filling the first region of the second layer where the dielectric precursor has been removed with a metal.

Aspect 3: The method of Aspect 1 further comprising, after removing the dielectric precursor composition in the first portion of the first layer exposed to radiation, applying a second layer of the dielectric composition, exposing, in an image-wise manner, a first region of the second layer of the dielectric precursor composition to radiation, said first region of the second layer overlapping with the removed first region of the first layer, to generate acid in the first region of the second layer exposed to the radiation, heating the exposed second layer to form cured dielectric resin in a second region of the second layer not exposed to the radiation; removing the dielectric precursor composition in the first region of the second layer forming a contiguous void region in the area where the first region of the first layer was removed and the region of the second layer was removed, and filling the contiguous void region with the metal.

Aspect 4: The method of Aspect 1 further comprising, after heating the exposed first layer to form the cured dielectric resin in the second portion of the first layer but before removing the first portion of the first layer exposed to the radiation, applying a second layer of the dielectric composition over the first layer, exposing, in an image-wise manner, a first region of the second layer of the dielectric precursor composition to radiation, said first region of the second layer overlapping with the first portion of the first layer, to generate acid in the first region of the second layer exposed to the radiation, heating the exposed second layer to form cured dielectric resin in a second region of the second layer not exposed to the radiation; removing the dielectric precursor composition in the exposed first portion of the first layer and the first region of the layer to form a contiguous void region, and filling the contiguous void region with the metal.

Aspect 5: The method of any one of the previous Aspects, wherein the cured dielectric resin comprises at least 38, preferably at least 40, more preferably at least 42, weight % percent silicon based on total weight of the cured dielectric resin.

Aspect 6: The method of any one of the previous Aspects wherein the silicon-containing polymeric resin is prepared from monomers with molecular structures of

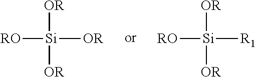

or combinations thereof wherein R is independently in each occurrence hydrogen or an alkyl of 1 to 4, preferably 1 to 3, and more preferably 1 or 2 carbon atoms, R is preferably an alkyl, of 1 or 2 carbon atoms, and R₁ is independently in each occurrence alkyl, aryl, alkene, alicyclic, epoxy-alkyl, or epoxy-cycloalkyl, R₁ is preferably alkyl of 1 or 2 carbon atoms, and polymerization taking place to said monomers with presence of a polymerization catalyst in an organic solvent at temperatures of from 80° C. to 110° C., with volatile alkanols being removed during polymerization to form the silicon-containing resin.

Aspect 7: The method of any one of the previous Aspects wherein the catalyst comprises a quaternary ammonium and/or an amine, preferably benzyltriethylammonium chloride (BTEAC), tetramethylammonium chloride (TMAC), guanidine carbonate, or tetramethylammonium hydroxide (TMAH).

Aspect 8: The method of any one of the previous Aspects wherein the catalyst is present in amounts of 0.0005 to 0.2, preferably 0.001 to 0.05, weight percent based on the of the dielectric precursor composition, or 0.005 to 4, preferably 0.01 to 0.5, weight percent based on the weight of the silicon-containing polymeric resin.

Aspect 9: The method of any one of the previous Aspects wherein the photoacid generator comprises onium salts, preferably sulfonium or iodonium salts, more preferably compounds of sulfonium cations and sulfonates or methides or iodonium cations and sulfonates.

Aspect 10: The method of any one of the previous Aspects wherein the mole ratio of photoacid generator to catalyst is 0.5:1 to 10:1.

Aspect 11: The method of any one of the previous Aspects wherein the radiation has a wavelength of 10 to 400 nm.

Aspect 12: The method of any one of the previous Aspects wherein the layer is exposed to the radiation in the image-wise manner through a mask or by address by a laser.

Aspect 13: The method of any of the previous Aspects wherein filling with metal comprises sputtering, vapor deposition, atomic layer deposition, or a combination of two or more thereof.

Aspect 14: The method of Aspect 1 wherein after filling with a metal, planarizing to remove excess metal and form an even surface.

Aspect 15: An article formed by the method of any one of Aspects 1-14.

Aspect 16: The article of Aspect 15 wherein the cured dielectric resin has a dielectric constant of less than 4, preferably less than 3.5.

Aspect 17: The article of Aspect 15 or 16 wherein the layer of cured dielectric resin does not crack at temperatures up to 400° C.

Aspect 18: A composition comprising a curable silicon-containing polymeric resin a catalyst capable of catalyzing condensation reaction of silicon-containing polymeric resin, a photoacid generator and one or more organic solvents wherein, when cured the resin comprises greater than 42, preferably at least 42.5, and more preferably at least 43 weight percent elemental silicon based on total weight of the cured resin. Aspect 19: The composition of Aspect 18 wherein the curable silicon-containing polymeric resin is the reaction product of monomers selected from the group consisting of: methyltrimethoxy silane, tetraethoxysilane, and combinations thereof.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g., “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure can alternately comprise, consist of, or consist essentially of, any appropriate components herein disclosed. The disclosure can additionally, or alternatively, be formulated so as to be devoid, or substantially free, of any components, materials, ingredients, adjuvants or species used in the prior art compositions or that are otherwise not necessary to the achievement of the function and/or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

1. A method of forming a metal interconnect in a dielectric material, the method comprising:
forming a first layer of a dielectric precursor composition on a substrate, the dielectric precursor composition comprising a silicon-containing polymeric resin, a catalyst capable of catalyzing condensation reaction of silicon-containing polymeric resin, and a photoacid generator, wherein the catalyst can be deactivated by the presence of acid such that it loses the capability of catalyzing the condensation reaction;
exposing a first portion of the first layer of the dielectric precursor composition to radiation in a first image-wise manner to generate acid in the first portion exposed to the radiation and form an exposed first layer;
heating the exposed first layer to form a cured dielectric resin in a second portion of the first layer not exposed to the radiation;
after the heating, removing the dielectric precursor composition in the first portion exposed to radiation; and
filling the first portion where the dielectric precursor has been removed with a metal.

2. The method of claim 1, further comprising:
after the filling of the first portion of the first layer where the dielectric precursor has been removed with the metal, applying a second layer of the dielectric precursor composition;
exposing a first region of the second layer of the dielectric precursor composition to radiation in a second image-wise manner to generate acid in the portion exposed to the radiation;
heating the exposed second layer to form cured dielectric resin in a second region of the second layer not exposed to the radiation;
removing the dielectric precursor composition in the first region of the second layer exposed to radiation; and
filling the first region of the second layer where the dielectric precursor has been removed with a metal.

3. The method of claim 1, further comprising, after the removing the dielectric precursor composition in the first portion of the first layer exposed to radiation:
applying a second layer of the dielectric composition;
exposing, in an image-wise manner, a first region of the second layer of the dielectric precursor composition to radiation, said first region of the second layer overlapping with the removed first portion of the first layer, to generate acid in the first portion of the second layer exposed to the radiation;
heating the exposed second layer to form a cured dielectric resin in a second region of the second layer not exposed to the radiation;
removing the dielectric precursor composition in the first region of the second layer forming a contiguous void region in the area where the portion of the first layer was removed and the portion of the second layer was removed; and
filling the contiguous void region with the metal.

4. The method of claim 1, further comprising:
after heating the exposed first layer to form the cured dielectric resin in the second portion of the first layer but before removing the first portion of the first layer exposed to the radiation, applying a second layer of the dielectric composition over the first layer;
exposing, in an image-wise manner, a first region of the second layer of the dielectric precursor composition to radiation, said first region of the second layer overlapping with the first portion of the first layer, to generate acid in the first region of the second layer exposed to the radiation;
heating the exposed second layer to form cured dielectric resin in a second region of the second layer not exposed to the radiation;
removing the dielectric precursor composition in the exposed first portion of the first layer and the first region of the layer to form a contiguous void region; and
filling the contiguous void region with the metal.

5. The method of claim 1, wherein the cured dielectric resin comprises at least 38 weight percent silicon, based on total weight of the cured dielectric resin.

6. The method of claim 1, wherein the silicon-containing polymeric resin is prepared from a monomer with molecular structures of 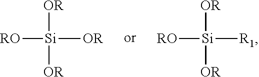
or a combination thereof, wherein each R is independently in each occurrence hydrogen or an alkyl of 1 to 4 carbon atoms, and R₁ is independently in each occurrence alkyl, aryl, alkene, alicyclic, epoxy-alkyl, or epoxy-cycloalkyl, and polymerization taking place to said monomers with presence of a polymerization catalyst in an organic solvent at a temperature of from 80° C. to 110° C., with a volatile alkanol being removed during polymerization, to form the silicon-containing resin.

7. The method of claim 1, wherein the catalyst comprises a quaternary ammonium and/or an amine.

8. The method of claim 1, wherein the catalyst is present in an amount of 0.0005 to 0.2 weight percent based on the total weight of the dielectric precursor composition, or 0.005 to 4 weight percent, based on the total weight of the silicon-containing polymeric resin.

9. The method of claim 1, wherein the photoacid generator comprises an onium salt.

10. The method of claim 1, wherein the mole ratio of the photoacid generator to the catalyst is 0.5:1 to 10:1.

11. The method of claim 1, wherein the radiation has a wavelength of 10 to 400 nanometers.

12. The method of claim 1, wherein the layer is exposed to the radiation in the image-wise manner through a mask or by address by a laser.

13. The method of claim 1, wherein the filling with metal comprises sputtering, vapor deposition, atomic layer deposition, or a combination of two or more thereof.

14. The method of claim 1, wherein after the filling with a metal, planarizing to remove excess metal and form an even surface.

15. An article formed by the method of claim 1.

16. The article of claim 15, wherein the cured dielectric resin has a dielectric constant of less than 4.

17. The article of claim 15, wherein the layer of cured dielectric resin does not crack at temperatures up to 400° C.

18. A composition comprising:
a curable silicon-containing polymeric resin,
a catalyst capable of catalyzing condensation reaction of silicon-containing polymeric resin,
a photoacid generator, and
an organic solvent,
wherein, when cured, the silicon-containing polymeric resin comprises greater than 42 weight percent elemental silicon, based on total weight of the cured resin.

19. The composition of claim 18, wherein the curable silicon-containing polymeric resin is a reaction product of monomers selected from the group consisting of: methyltrimethoxy silane, tetraethoxysilane, and combinations thereof.

20. The method of claim 9, wherein the photoacid generator comprises a sulfonium or an iodonium salt.
